(19) United States
(12) Patent Application Publication
(10) Pub. No.: US 2026/0344327 A1
(43) Pub. Date: Oct. 29, 2026

(54) COOLING DEVICE, SUBSTRATE PROCESSING APPARATUS AND COOLING METHOD

(71) Applicant: SCREEN Holdings Co., Ltd., Kyoto (JP)

(72) Inventors: Tomoaki AIHARA, Kyoto (JP); Tetsuya WATANABE, Kyoto (JP)

(21) Appl. No.: 19/569,266

(22) Filed: Mar. 17, 2026

(30) Foreign Application Priority Data
Mar. 25, 2025 (JP) 2025-049597

(51) Int. Cl. H10P 72/00

(52) U.S. Cl. CPC H10P 72/0404

(57) ABSTRACT

A cooling device according to the present invention comprises a cooling medium supplier for supplying a cooling medium, a heat exchanger for cooling the cooling medium through heat exchange with the cooling medium, a processing liquid supplier for supplying the processing liquid, and a pressure regulator for regulating the pressure of the cooling medium inside the current space and the processing liquid in the internal space. The heat exchanger includes a housing with a current space in which the cooling medium flows and an inner pipe made of resin provided in the current space. The pressure regulator regulates the pressure at least one of the cooling medium and the processing liquid in such a way that the pressure of the processing liquid becomes higher than the pressure of the cooling medium between the cooling medium in the current space and the processing liquid in the inner pipe.

### CROSS REFERENCE TO RELATED APPLICATION

The disclosure of Japanese Patent Application No.2025-049597 filed on Mar. 25, 2025 including specification, drawings and claims is incorporated herein by reference in its entirety.

### BACKGROUND OF THE INVENTION

### 1. Field of the Invention

This invention relates to a technique of cooling and outputting a processing liquid to be used, for example, for processing a substrate.

### 2. Description of the Related Art

In a process of manufacturing various kinds of substrates such as semiconductor substrates or glass substrates, for example, processing liquids at various temperatures having various compositions are used for processing the substrates. In some cases, water prepared by cooling high-purity water such as de-ionized water or pure water to a temperature around its freezing point (0 °C) (resultant water is simply called “cool water” herein) is required to be used as these processing liquids. As an example, according to a technique shown in JP2024-134431A (Patent Literature 1) disclosed previously by the applicant of the present application, de-ionized water (DIW) temperature-regulated to a low temperature is used as a cooling medium and brought into contact with a back surface of a substrate for the purpose of cooling the substrate heated during a course of a process.

Patent Literature 1 states that a chiller is applicable as a cooling device for cooling the cooling medium. While Patent Literature 1 does not provide specific statement, a chiller is generally used for cooling a fluid by applying cold energy to the fluid flowing in a pipe. In addition to a type of using the Peltier effect shown as an example, the chiller employs a type of exchanging heat with a cooling target fluid using a cooling medium. As a pipe in such a chiller for causing the cooling target fluid to flow therein, a pipe made of metal such as copper is used mainly from the viewpoint mainly of cooling efficiency and mechanical strength.

Metal ions to become a contamination source are required to be removed thoroughly from every processing liquid used in a step of processing a substrate such as a semiconductor substrate, in particular, from a processing liquid to come into direct contact with the substrate. In response to this, DIW is used as a cooling medium in the above conventional technique. If the chiller for cooling the DIW uses a metal pipe, however, mixture of metal ions into the DIW is unavoidable. While mixture of metal ions becomes avoidable by using a pipe made of resin such as fluorine resin, for example, instead of the metal pipe, this causes reduction in mechanical strength compared to use of the metal pipe. In particular, in the case of a cooling device of a type of cooling a processing liquid through heat exchange with a cooling medium, if impurity such as a cooling medium is mixed into the processing liquid due to break in a pipe, a substrate is contaminated in response to touch of the substrate with the processing liquid in this state.

In view of the above circumstances, a cooling device still applicable to a case of bringing a processing liquid cooled in a way like the above conventional technique into direct contact with a substrate is required to use a resin pipe instead of a metal pipe that might become a contamination source, and required to cause no mixture of impurity due to break in the pipe. However, such a cooling device has not yet been put into practical use.

### SUMMARY OF THE INVENTION

This invention has been made in view of the above problem, and is intended to provide a technique allowing a processing liquid to be cooled to a desired temperature without causing mixture of impurity.

One aspect of the present invention is intended for a cooling device configured for cooling a processing liquid and outputting the processing liquid. The cooling device comprises: a cooling medium supplier configured to supply a cooling medium at a lower temperature than a cooling target temperature of the processing liquid; a heat exchanger configured to cool the processing liquid through heat exchange with the cooling medium, the heat exchanger including a housing with a current space for causing the cooling medium supplied from the cooling medium supplier to flow therein, and an inner pipe that is a resin pipe provided in and penetrating the current space in such a way that an outer surface of a pipe wall of the inner pipe borders the current space and an internal space of the inner pipe is separated from the current space; a processing liquid supplier configured to supply the processing liquid as a cooling target from one end of the inner pipe into the internal space of the inner pipe; and a pressure regulator configured to regulate the pressure of the cooling medium inside the current space and the pressure of the processing liquid in the internal space.

Here, the pressure regulator regulates the pressure of at least one of the cooling medium and the processing liquid in such a way that the pressure of the processing liquid becomes higher than the pressure of the cooling medium between the cooling medium and the processing liquid facing each other across the pipe wall in the current space, and the cooled processing liquid is output from the other end of the inner pipe opposite to the one end.

Another aspect of the present invention is intended for a cooling method configured to cool a processing liquid and output the processing liquid. In a heat exchanger including a housing with a current space for causing a cooling medium to flow therein, and an inner pipe that is a resin pipe provided in and penetrating the current space in such a way that an outer surface of a pipe wall of the inner pipe borders the current space and an internal space of the inner pipe is separated from the current space, the cooling medium at a lower temperature than a cooling target temperature of the processing liquid is caused to flow in the current space. The processing liquid as a cooling target is caused to flow in the internal space of the inner pipe, and the pressure of at least one of the cooling medium and the processing liquid is regulated in such a way that the pressure of the processing liquid becomes higher than the pressure of the cooling medium between the cooling medium and the processing liquid facing each other across the pipe wall in the current space. The cooled processing liquid is output from the other end of the inner pipe opposite into the one end.

According to the invention having the above configuration, heat is exchanged between the processing liquid to be cooled and the cooling medium across the pipe wall of the inner pipe in the heat exchanger, thereby cooling the processing liquid. As the inner pipe to come into direct contact with the processing liquid is made of resin, the problem of mixture of metal ions is settled. On the other hand, the resin pipe is lower in mechanical strength than a metal pipe. Hence, countermeasures are required to be taken for preventing mixture of the cooling medium into the processing liquid and preventing contamination of a subject to be processed even on the occurrence of break such as a crack in the inner pipe.

According to the present invention, the pressure of the cooling medium and that of the processing liquid are controlled in such a way as to bring the processing liquid to a higher pressure between the processing liquid and the cooling medium separated from each other by the pipe wall of the inner pipe. Even if a crack or the like is caused in the inner pipe, while it is probable that the processing liquid will leach out from the inner pipe into the current space to be mixed with the cooling medium, a resultant pressure difference still avoids mixture of the cooling medium or impurity in the cooling medium into the processing liquid flowing in the inner pipe. This prevents the occurrence of a situation where the processing liquid containing impurity such as the cooling medium will be output.

As described above, according to the present invention, the processing liquid is controlled to a higher pressure between the cooling medium and the processing liquid separated from each other by the pipe wall. Thus, even on the occurrence of a crack or the like in the pipe wall, it is still possible to prevent mixture of a component in the cooling medium into the processing liquid.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 shows a schematic configuration of a substrate processing system including a cooling device according to one embodiment of the present invention;

FIG. 2 shows an exemplary configuration of the cooling device;

FIGS. 3A to 3C show an exemplary configuration of the heat exchanger;

FIGS. 4A and 4B show a relationship between the pressure of the cooling medium and that of the DIW in this embodiment;

FIGS. 5A and 5B show principles of control over the pressure of the cooling medium and that of the DIW in the heat exchanger; and

FIG. 6 shows an exemplary control method implemented when the cooling devices are connected in multiple stages.

### DETAILED DESCRIPTION OF THE PREFERRED EMBODIMENTS

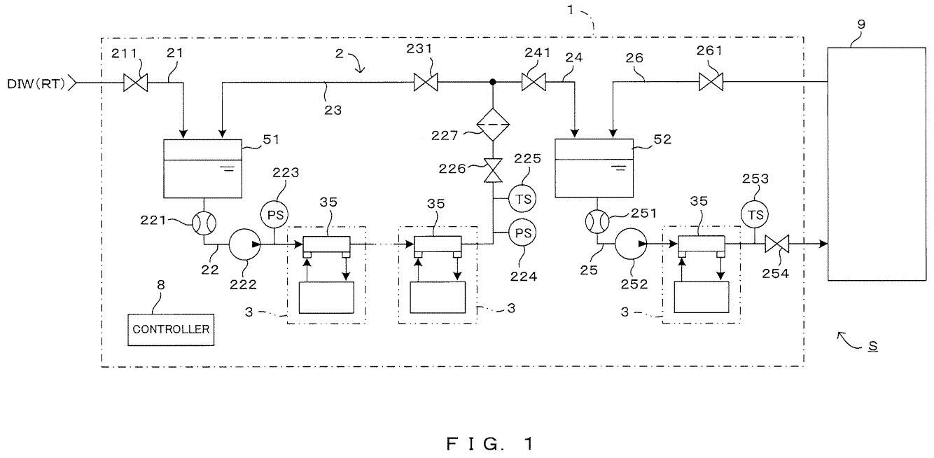

FIG. 1 shows a schematic configuration of a substrate processing system including a cooling device according to one embodiment of the present invention. This substrate processing system S includes a processing liquid supplier 1 and a substrate processor 9. The processing liquid supplier 1 cools pure water or de-ionized water supplied from an external supply source to a predetermined temperature and outputs the cooled water as a processing liquid. The substrate processor 9 processes a processing target substrate using the processing liquid supplied from the processing liquid supplier 1. In the following, DIW will be described as a representative of the processing liquid. The substrate processor 9 may be configured to supply this processing liquid as it is to the substrate, or may be configured to mix the processing liquid with a different type of chemical or an organic solvent such as isopropyl alcohol (IPA) and supply a resultant liquid to the substrate, for example. While a semiconductor wafer is applicable as the substrate to be processed, for example, the substrate is not limited to this. While a representative process by the substrate processor 9 includes a rinsing process, wet cleaning, and wet etching performed by supplying a processing liquid, a chemical or the like to the substrate, it is not particularly limited.

The processing liquid supplier 1 includes a pipe system 2 for supplying the DIW to the substrate processor 9. Various types of functional units are provided appropriately along the piping to form a flow path of the processing liquid. More specifically, a control valve 211 is interposed in a pipe 21 connected to an external DIW supply source, and a terminal of the pipe 21 is connected to a primary reservoir tank 51. When the control valve 211 is opened in response to a control command from a controller 8 responsible for control over the behavior of the device as a whole, the DIW at room temperature (RT) supplied from the outside flows into the primary reservoir tank 51 through the pipe 21.

In the following, terms “flow direction,” “upstream side,” and “downstream side” are used for defining positions along a flow path of the processing liquid or a cooling medium. Unless specified otherwise, these terms show a flow direction of a liquid at a corresponding position along the flow path, and an upstream side and a downstream side of this flow direction.

A pipe 22 is connected to a lower part of the primary reservoir tank 51. A flowmeter 221, a feed pump 222, a pressure sensor 223, a cooling device 3, a pressure sensor 224, a temperature sensor 225, a control valve 226, a filter 227, and others are connected to the pipe 22. Each of these functional units may be added appropriately, as needed, to a position other than the illustrated position, or some of these functional units may be omitted. As an example, pressure reduction between the upstream side (primary side) and the downstream side (secondary side) with respect to a heat exchanger 35 caused by pressure loss at the heat exchanger 35 can be acquired as data or can be calculated through experiment or simulation conducted previously. Thus, in one configuration, the pressure sensor 224 on the downstream side with respect to the heat exchanger 35 may be omitted.

Each of the flowmeter 221 and flowmeters described later detects the flow rate of a liquid in a flow path. Each of the feed pump 222 and feed pumps described later feeds a liquid supplied from the upstream side of the flow path toward the downstream side. Each of the pressure sensor 224 and pressure sensors described later detects the pressure of the liquid in the flow path. Each of the temperature sensor 225 and temperature sensors described later detects the temperature of the liquid in the flow path.

Each of the flowmeters, the feed pumps, the pressure sensors, and the temperature sensors is communicably connected to the controller 8. An output signal from each of the flowmeters, the pressure sensors, and the temperature sensors is transmitted to the controller 8. Each feed pumps and each control valves described later operate in response to a control command from the controller 8 to regulate the flow of the processing liquid in the flow path. The controller 8 controls the behaviors of movable parts including the feed pumps and the control valves in response to a control program prepared in advance and signals transmitted from sensors including the flowmeters, the pressure sensors, and the temperature sensors.

The cooling device 3 has the function of reducing the temperature of an incoming liquid and outputting the resultant liquid. A final temperature of the processing liquid to be output from the cooling device 3 is not particularly limited. Meanwhile, the final temperature may be set to a temperature lower than room temperature and slightly higher than 0 °C as a freezing point of the DIW, for example, and may be set to 5 °C, for example. The number of the cooling devices 3 may be one. Meanwhile, in order to reduce the temperature of the processing liquid supplied at room temperature efficiently in shorter time to a target temperature, two or more cooling devices 3 may be connected in series with each other, for example. In order to increase the quantity of the processing liquid to be cooled, two or more cooling devices 3 may be connected in parallel. The cooling device 3 will be described later in detail.

The pipe 22 branches on the downstream side with respect to the filter 227 into a pipe 23 and a pipe 24. A control valve 231 is interposed in the pipe 23, and a terminal of the pipe 23 is connected to the primary reservoir tank 51. Specifically, the pipes 22 and 23 function as a circulation flow path of causing the processing liquid to circulate with respect to the primary reservoir tank 51. As the feed pump 222 for feeding the processing liquid under pressure and the cooling device 3 for cooling the processing liquid are interposed in the pipe 22, the processing liquid circulates through the circulation flow path to maintain the processing liquid in the primary reservoir tank 51 at a predetermined temperature lower than room temperature.

A control valve 241 is interposed in the other pipe 24, and a terminal of the pipe 24 is connected to a secondary reservoir tank 52. The cooled processing liquid passed through the pipe 24 flows into the secondary reservoir tank 52, and the secondary reservoir tank 52 stores the processing liquid therein.

A pipe 25 is connected to a lower part of the secondary reservoir tank 52. A flowmeter 251, a feed pump 252, a cooling device 3, a temperature sensor 253, a control valve 254, and others are connected to the pipe 25. Each of these functional units may be added appropriately, as needed, to a position other than the illustrated position, or some of these functional units may be omitted. A terminal of the pipe 25 is connected to the substrate processor 9. The processing liquid supplied from the secondary reservoir tank 52 is fed under pressure by the feed pump 252 toward the downstream side. The processing liquid finally temperature-regulated by the cooling device 3 is fed to the substrate processor 9 through the control valve 254.

The substrate processor 9 and the secondary reservoir tank 52 are connected to each other by a return pipe 26. A control valve 261 is interposed in the return pipe 26. The processing liquid returning from the substrate processor 9 flows into the secondary reservoir tank 52 through the return pipe 26. In this way, the pipes 25 and 26 form a circulation flow path including the substrate processor 9, and the cooling device 3 is provided along the circulation flow path. This allows the processing liquid stable in temperature to the substrate processor 9.

The pipes and the functional units forming the pipe system 2 are each made of a resin material in a part to contact the processing liquid. As an example, fluorine resin such as perfluoroalkoxy alkane (PFA) resin or polytetra fluoroethylene (PTFE) resin is preferably applicable as a material not to cause release of impurity such as metal ions into the processing liquid.

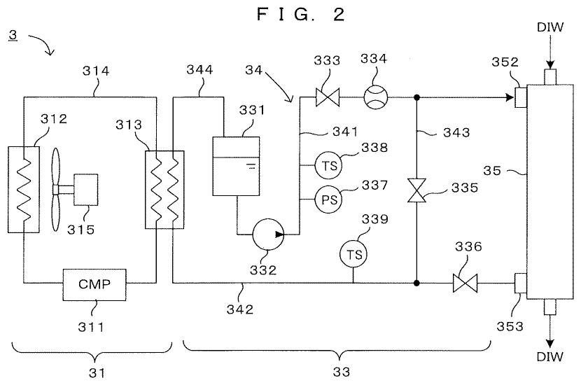

FIG. 2 shows an exemplary configuration of the cooling device. Main structures of the cooling device 3 include a refrigerating circuit 31, a circulating liquid circuit 33, and the heat exchanger 35. A circuit already available as a product can be used as the refrigerating circuit 31. Thus, only a minimum configuration required for explanation of principles is shown in the drawings and the operation thereof will be described simply. Regarding a pressure sensor and a temperature sensor appropriately provided along the flow path as necessary, descriptions of these sensors will also be omitted.

In the cooling device 3, a first cooling medium cooled by the refrigerating circuit 31 is used to cool a second cooling medium to circulate in the circulating liquid circuit 33, and the heat exchanger 35 cools the processing liquid using the second cooling medium thereby cooled. By doing so, the processing liquid is cooled to a desired cooling target temperature. Cooling the processing liquid in this way by the two-stage cooling process using the intervening circulating liquid circuit 33 is intended to eliminate metal to become a contamination source from the pipes and others to be touched by the DIW as the processing liquid, thereby outputting high-purity DIW.

The refrigerating circuit 31 is a so-called chiller, and includes a compressor (compression machine) 311, an air-cooled condenser 312, an evaporator 313, and a pipe 314 connecting these parts to form a circulation flow path. An appropriate cooling medium (first cooling medium) that may be chlorofluorocarbons or a substitute for chlorofluorocarbons, for example, is poured under a high pressure in the circulation flow path. The cooling medium compressed and pressurized by the compressor 311 and the air-cooled condenser 312 is vaporized by the evaporator 313. During the vaporization, heat is drawn from the surrounding to cool a target. Here, a cooling target is the second cooling medium poured in the circulating liquid circuit 33.

A fan motor 315 is arranged near the air-cooled condenser 312, and dissipates heat of condensation generated by the first cooling medium to the outside. While not shown in the drawings, functional units including an expansion valve, a pressure sensor, and a temperature sensor are provided at appropriate positions in the refrigerating circuit 31.

The circulating liquid circuit 33 feeds the cooling medium (second cooling medium) having been cooled by the refrigerating circuit 31 to the heat exchanger 35 in the next stage. For this purpose, the circulating liquid circuit 33 has a configuration where a reservoir tank 331, a feed pump 332, control valves 333, 335, and 336, a flowmeter 334 and others are interposed in a pipe 34. More specifically, the pipe 34 includes a pipe 341 forming connection between a lower part of the reservoir tank 331 and an input port 352 of the heat exchanger 35, a pipe 342 forming connection between an output port 353 of the heat exchanger 35 and the evaporator 313, a pipe 343 forming connection between the pipe 341 and the pipe 342, and a pipe 344 forming connection between the evaporator 313 and the reservoir tank 331.

The feed pump 332, the control valve 333, and the flowmeter 334 are interposed in the pipe 341. The control valve 336 is interposed in the pipe 342. The pipe 343 is provided in such a way as to form connection between the downstream side of the pipe 341 with respect to the flowmeter 334 and the downstream side of the pipe 342 with respect to the control valve 336, and the control valve 335 is provided along a flow path in the pipe 343.

When the feed pump 332 feeds the cooling medium under pressure and the control valve 333 is opened in response to a control command from the controller 8, the cooling medium fed from the reservoir tank 331 is supplied to the heat exchanger 35. By opening the control valve 336, the cooling medium returning from the heat exchanger 35 is allowed to be received in the pipe 342. By opening the control valve 335, the cooling medium fed by the feed pump 332 is allowed to flow at least partially or entirely into the pipe 342 while bypassing the heat exchanger 35.

The cooling medium having flowed into the pipe 342 flows back into the reservoir tank 331 through the evaporator 313 and the pipe 344. In this way, a flow path for causing the cooling medium (second cooling medium) to circulate from the reservoir tank 331 through the evaporator 313 is formed in the circulating liquid circuit 33, and the second cooling medium cooled by the evaporator 313 circulates in the circulating liquid circuit 33. As a result, the temperature of the circulating cooling medium is stabilized.

A pressure sensor 337 and a temperature sensor 338 are provided on the downstream side of the pipe 341 with respect to the feed pump 332. An additional temperature sensor 339 is provided on the downstream side of the pipe 342 with respect to a point of merging with the pipe 343. The controller 8 controls the feed pump 332 and the control valves 333, 335 and 336 on the basis of output signals from these sensors, thereby feeding the cooling medium at a predetermined temperature and a predetermined flow rate into the heat exchanger 35.

A liquid to be used as the second cooling medium is a liquid coolable to a lower temperature than a final cooling target temperature of the processing liquid (in this example, 5 °C and this temperature will be called a “final target temperature”) without being coagulated by freezing. For example, ethylene glycol (EG) having a melting point of minus 13 °C or an aqueous solution thereof is preferably available. Regarding the temperature of the second cooling medium, the second cooling medium is maintained at a lower temperature than the target temperature of the processing liquid to be output from the cooling device 3.

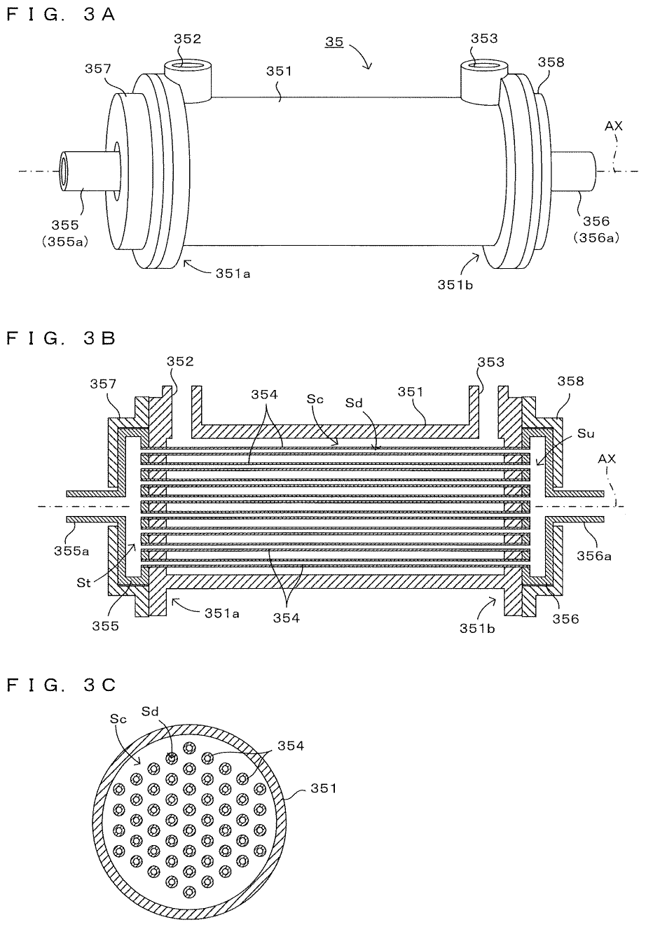

FIGS. 3A to 3C show an exemplary configuration of the heat exchanger. More specifically, FIG. 3A shows the appearance of the heat exchanger 35. In FIG. 3A, a dash-dot line shows a virtual center axis AX of the heat exchanger 35. FIG. 3B is a longitudinal sectional view showing a section of the heat exchanger 35 along the center axis AX. FIG. 3C is a cross sectional view showing a section perpendicular to the center axis AX.

The heat exchanger 35 includes a housing 351 having a substantially circular columnar outer shape with a hollow interior extending along the center axis AX, in other words, having a circular cylindrical shape with closed opposite ends. The housing 351 has a side surface where the input port 352 is provided at a position close to one edge 351a of the housing 351, and the output port 353 is provided at a position close to the other edge 351b of the housing 351 opposite to the one edge 351a. The cooling medium fed from the circulating liquid circuit 33 flows through the input port 352 into an internal space defined by an inner wall of the housing 351, and flows out through the output port 353. The cooling medium having flowed into the internal space of the housing 351 fills an external side of an inner pipe inserted in and passed through the internal space and used for causing the DIW to flow therein. In the internal space of the housing 351, a space except the inner pipe and except a space in the inner pipe is called a current space Sc. The cooling medium supplied from the circulating liquid circuit 33 to the heat exchanger 35 flows in the current space Sc.

The housing 351 includes a plurality of inner pipes 354 inserted in and passed through the housing 351 and penetrating the current space Sc from the one edge 351a to the other edge 351b of the housing 351. On the side of the one edge 351a, the inner pipe 354 is terminated by a terminal member 355 and an internal space Sd of the inner pipe 354 communicates with an internal space St of the terminal member 355. Likewise, on the side of the other edge 351b, the inner pipe 354 is terminated by a terminal member 356 and the internal space Sd of the inner pipe 354 communicates with an internal space Su of the terminal member 356. As a result, the respective internal spaces St and Su of the terminal members 355 and 356 communicate with each other via the internal space Sd of the inner pipe 354.

An input port 355a for receiving the DIW to be cooled is provided at an end of the terminal member 355. An output port 356a for feeding the DIW is provided at an end of the terminal member 356. The input port 355a connects to one end of each of the inner pipes 354, and the other end of each inner pipe 354 connects to the output port 356a. Thus, the inner pipes 354 have a parallel relationship with each other in terms of a flow path of the DIW. The DIW having flowed into the internal space St from the input port 355a branches into flows to enter the inner pipes 354, passes through the internal space Sd of each inner pipe 354 to flow out into the internal space Su, and is then fed through the output port 356a toward the downstream side with respect to the heat exchanger 35. Specifically, the terminal member 355 and the inner pipes 354 function as a manifold for branching the DIW, and the inner pipes 354 and the terminal member 356 function as a manifold for merging the flows of the DIW.

In the following, if the input port 355a and the input port 352 are required to be distinguished from each other, they will be called an “input port 355a for DIW” and an “input port 352 for cooling medium.” Likewise, if the output port 356a and the output port 353 are required to be distinguished from each other, they will be called an “output port 356a for DIW” and an “output port 353 for cooling medium.”

The inner pipe 354 and the terminal members 355 and 356 are made of resin materials not to cause release of impurity such as metal ions. Like the other pipes, the inner pipe 354 and the terminal members 355 and 356 are formed by using a material that is preferably a fluorine resin material such as PFA resin, for example. As an example, a PFA tube is available as the inner pipe 354. Regarding the terminal members 355 and 356 each required to be processed into a complicated shape, PTFE resin is available in addition to PFA resin. The terminal members 355 and 356 can be formed into the same shape.

The terminal members 355 and 356 are fixed to the housing 351 by cover members 357 and 358 respectively. Specifically, the terminal member 355 is mounted on the one edge 351a of the housing 351 in such a way as to be interposed between the one edge 351a of the housing 351 and the cover member 357. Likewise, the terminal member 356 is mounted on the other edge 351b of the housing 351 in such a way as to be interposed between the other edge 351b of the housing 351 and the cover member 358. The cover members 357 and 358 can be formed into the same shape.

The housing 351 and the cover members 357 and 358 are each made of metal such as stainless steel, for example, and are coupled to each other with coupling members such as bolts not shown in the drawings. As will be described later, while each of the cooling medium and the DIW is supplied to the heat exchanger 35 in a pressurized state, forming the housing 351 using solid metal provides resistance to such a pressure. The resin terminal members 355 and 356 themselves do not have high resistances to such a pressure. However, reinforcing the terminal members 355 and 356 from outside using the cover members 357 and 358 allows the terminal members 355 and 356 to be resistant to such a pressure.

The current space Sc and the internal space Sd of the inner pipe 354 are separated from each other by a pipe wall of the inner pipe 354, and the cooling medium flowing in the current space Sc and the DIW flowing in the internal space Sd are separated from each other. An outer surface of the pipe wall touches the cooling medium at a low temperature. Thus, the DIW is cooled through heat exchange with the cooling medium across the pipe wall, and is output from the output port 356a at a lower temperature than the temperature of the DIW during input from the input port 355a. As the inner pipes 354 are inserted in and passed through the interior of the housing 351, the DIW is cooled at high efficiency.

If the cooling devices 3 are connected in multiple stages, a cooling target temperature at each cooling device 3 is not required to be the final target temperature. Specifically, in a configuration of bringing the DIW to the final target temperature stepwise using the cooling devices 3 in multiple stages, a temperature reduction required to be attained in each cooling device 3 can be smaller. In this case, each of the temperature of the DIW to be input and the temperature of the DIW to be output differs between the cooling devices 3, so that the cooling devices 3 are not always required to be the same in terms of respective configurations and specifications.

In the above configuration, the cooling medium flowing in the current space Sc and the DIW flowing in the internal space Sd of the inner pipe 354 do not come into contact with each other. The DIW is passed through inside the resin pipe. As a result, mixture of impurity such as a component in the cooling medium or metal ions into the DIW is avoided. However, if a high pressure is applied to the inner pipe 354 that is a resin pipe not always having high mechanical strength to cause a crack or the like in the inner pipe 354, such impurity might be mixed into the DIW. This is prevented by taking countermeasures described below.

In this embodiment, the above problem is handled by regulating the pressure of the cooling medium and that of the DIW to be supplied to the heat exchanger 35. Specifically, if a crack occurs in the pipe wall of the inner pipe 354, leaching of a liquid might be caused by a pressure difference between liquids existing across the pipe wall. If the pressure of the cooling medium is higher than the pressure of the DIW, the cooling medium leaches out from the current space Sc toward the internal space Sd of the inner pipe 354. This means mixture of the cooling medium into the DIW flowing in the inner pipe 354.

On the other hand, if the pressure of the DIW is higher than the pressure of the cooling medium, mixture of the cooling medium into the DIW flowing in the inner pipe 354 is avoided while the DIW might leach out into the current space Sc to be mixed into the cooling medium. In this embodiment, control is performed over the cooling medium and/or the DIW in terms of pressure in the heat exchanger 35 in such a way as to bring the DIW to a higher pressure between the cooling medium and the DIW existing across the pipe wall of the inner pipe 354 in the current space Sc.

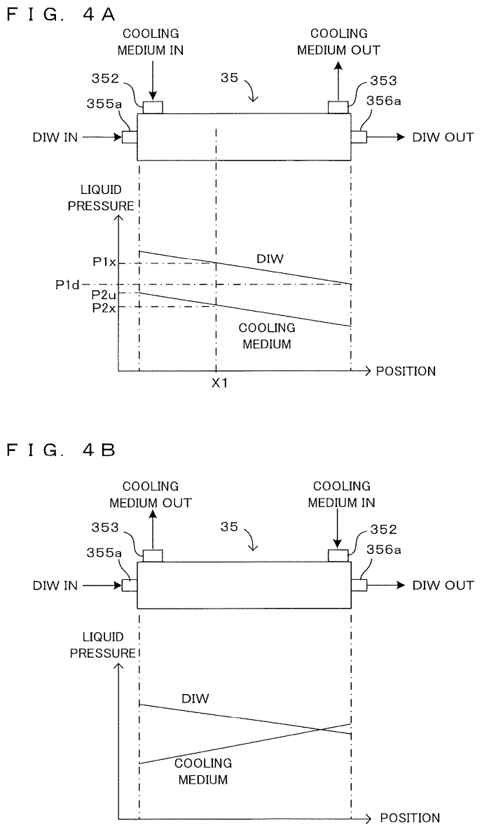

FIGS. 4A and 4B show a relationship between the pressure of the cooling medium and that of the DIW in this embodiment. In the example shown in FIG. 4A, a flow direction of the cooling medium and a flow direction of the DIW are the same in the heat exchanger 35. In the example shown in FIG. 4A, the input port 352 for the cooling medium and the input port 355a for the DIW are provided at a left end of the housing 351, and the output port 353 for the cooling medium and the output port 356a for the DIW are provided at a right end of the housing 351. In the housing 351, both the cooling medium and the DIW flow from left to right in FIG. 4A.

The pressure of the cooling medium in the housing 351 is highest in the vicinity of the input port 352 on the most upstream side, and the pressure decreases toward the downstream side, namely, toward the right. For simplicity, it is assumed that the pressure decrease linearly in FIG. 4A. While actual change in the pressure exhibits a more complicated behavior, the pressure of the cooling medium generally tends to decrease monotonously toward the downstream side.

The DIW shows a similar tendency. The pressure of the DIW and the pressure of the cooling medium at a position X1 in an axial direction of the housing 351 are indicated by a sign P1x and a sign P2x respectively. As long as a relationship P1x>P2x is established at the arbitrary position X1, even on the occurrence of a crack or the like in the inner pipe 354, it is still possible to reduce a likelihood of mixture of the cooling medium into the DIW flowing in the inner pipe 354.

As described above, the pressure tends to decrease monotonously toward the downstream side in the configuration in FIG. 4A. Thus, making a pressure P1d of the DIW on the most downstream side higher than a pressure P2u of the cooling medium on the most upstream side attains a state where the pressure of the DIW is reliably higher than the pressure of the cooling medium in the current space Sc entirely. If large pressure loss occurs in the inner pipe 354 to result in a large pressure gradient of the DIW, the pressure of the DIW on the most upstream side is required to be increased in order to ensure a sufficient pressure of the DIW even on the most downstream side.

However, increasing the pressure of the DIW only on the most upstream side may generate a place where a considerably large pressure difference occurs between the interior and the exterior of the pipe wall of the inner pipe 354. This might conversely cause the risk of break in the inner pipe 354. This problem is avoided by controlling a pressure on the most upstream side and a pressure on the most downstream side about each of the cooling medium and the DIW to make the pressure of the DIW higher both on the most upstream side and on the most downstream side. If the cooling medium and the DIW have pressure gradients substantially equal to each other, for example, creating a condition for bringing the DIW to a higher pressure on one of the most upstream side and the most downstream side necessarily creates a corresponding condition on the other side.

If the precondition that the pressure of the DIW input to the heat exchanger 35 be higher than the pressure of the cooling medium input to the heat exchanger 35 is fulfilled, making the pressure of the DIW detected on the output side higher than the pressure of the cooling medium to be output allows the above relationship P1x>P2x to be established at the arbitrary position X1 in the heat exchanger 35. Thus, the control valve 226 may be controlled on the basis of pressure detection result from the pressure sensor 224, for example. This makes it possible to conduct pressure regulation comparatively simply.

In a situation where the DIW has a larger pressure gradient in the heat exchanger 35, the pressure of the DIW at the output port 356a may be increased by providing a place of large pressure loss in a flow path of the DIW on the downstream side with respect to the heat exchanger 35. By doing so, the pressure gradient in the heat exchanger 35 can become gentle to be approximated to that of the cooling medium. This makes it possible to reduce a difference in pressure between the DIW and the cooling medium applied to the pipe wall of the inner pipe 354, allowing the inner pipe 354 to be less likely to be damaged.

To be more simple, a pressure at each part can be determined on the basis of result of preparatory experiment. Specifically, respective pressure losses in the flow paths of the cooling medium and the DIW in the heat exchanger 35 may be determined experimentally, respective pressure distributions of the cooling medium and the DIW may be estimated from the determined pressure losses, the magnitudes of pressures during input and output of each of the cooling medium and the DIW may be calculated, and control may be performed on each part in such a way as to attain the calculated pressures. Experiment conducted by the inventors of the present application shows that an appropriate pressure of the DIW on the input side is obtained by calculating a sum of the magnitude of the pressure of the cooling medium on the output side and pressure loss in the DIW flow path and adding a margin of about 10% to the sum, for example.

FIG. 4B shows a configuration given as a comparative example where the positions of the input port 352 and the output port 353 for the cooling medium relative to each other are reversed from those of this embodiment. Specifically, in the comparative example, the cooling medium flows from right to left in the drawing. In this case, while a pressure gradient of the DIW still slopes right down, a pressure gradient of the cooling medium slops right up. Therefore, in order for the DIW to maintain a higher pressure than the cooling medium even on the most downstream side, the pressure of the DIW to be input is required to be increased further. This accelerates degradation of the inner pipe 354 as described above. Thus, from the viewpoint of reducing the risk of break in the inner pipe, it is more preferable that the cooling medium and the DIW flow in the same flow direction like in this embodiment shown in FIG. 4A. On the other hand, from the viewpoint of heat exchange efficiency, it is preferable that the cooling medium and the DIW flow in reverse directions as shown in FIG. 4B.

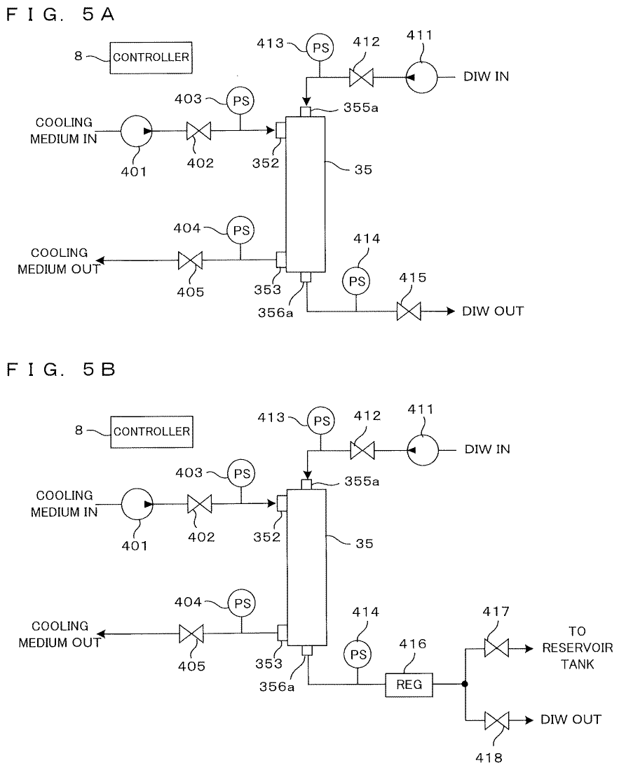

FIGS. 5A and 5B show principles of control over the pressure of the cooling medium and that of the DIW in the heat exchanger. In a case discussed herein, one heat exchanger 35 is interposed in a flow path for explanation of the principles. This configuration differs from an actual device configuration, so that functional units other than the heat exchanger 35 are given signs differing from those of the embodiment.

In order to fulfill the condition that the DIW to be input to the heat exchanger 35 have a higher pressure than the cooling medium to be input and the DIW to be output also have a higher pressure than the cooling medium to be output, the pressures of the DIW to be input and to be output and the pressures of the cooling medium to be input and to be output may be detected, and the quantities of the DIW to be input and to be output and the quantities of the cooling medium to be input and to be output may be regulated on the basis of results of the detections. In principle, a preferred relationship between pressures can be attained by controlling at least one of the pressure of the cooling medium to be input to the heat exchanger 35 and the pressure of the cooling medium to be output from the heat exchanger 35, and at least one of the pressure of the DIW to be input to the heat exchanger 35 and the pressure of the DIW to be output from the heat exchanger 35.

As shown in FIG. 5A, in a configuration where the cooling medium is input from a feed pump 401 to the input port 352 through a control valve 402 and is then collected from the output port 353 through a control valve 405, the pressure of the cooling medium can be regulated by providing pressure sensors 403 and 404 in an input flow path and an output flow path respectively, and controlling the quantity of feed from the feed pump 401 and the degrees of opening of the control valves 402 and 405 in response to detection results from the pressure sensors 403 and 405.

In a configuration relating to a flow path of the DIW where the DIW is input from a feed pump 411 to the input port 355a through a control valve 412 and is then collected from the output port 356a through a control valve 415, the pressure of the DIW can be regulated by providing pressure sensors 413 and 414 in an input flow path and an output flow path respectively, and controlling the quantity of feed from the feed pump 411 and the degrees of opening of the control valves 412 and 415 in response to detection results from the pressure sensors 413 and 414.

Thus, with the feed pumps 401 and 411 and some of the control valves 402, 405, 412 and 415 defined as control subjects, by causing the controller 8 to control the control subjects on the basis of output signals from the pressure sensors 403, 404, 413 and 414, it becomes possible to achieve an intended relationship between pressures. For example, a relief valve or a motor needle valve is available as a control valve appropriate for such pressure control. In particular, a relief valve is further operable as a regulator 416 described in the following example. In the absence of the need to control a pressure dynamically, pressure loss may be generated by interposing an orifice in a flow path.

If output from the heat exchanger 35 branches into a circulation flow path toward a reservoir tank and an output flow path for output to the outside like in this embodiment, performing pressure control on the output side of the DIW using the control valve 415 is not a realistic way. Reason for this is that, in some cases, the necessity to ensure the quantity of the DIW required in the outside makes it impossible to set the degree of opening of the control valve 415 freely. In such a case, as shown in FIG. 5B, it is preferable to make pressure regulation using the regulator 416 provided on the output side of the DIW, form branches on the downstream side with respect to the regulator 416 into a pipe toward a reservoir tank and a pipe for output to the outside, and provide control valves 417 and 418 in the corresponding pipes.

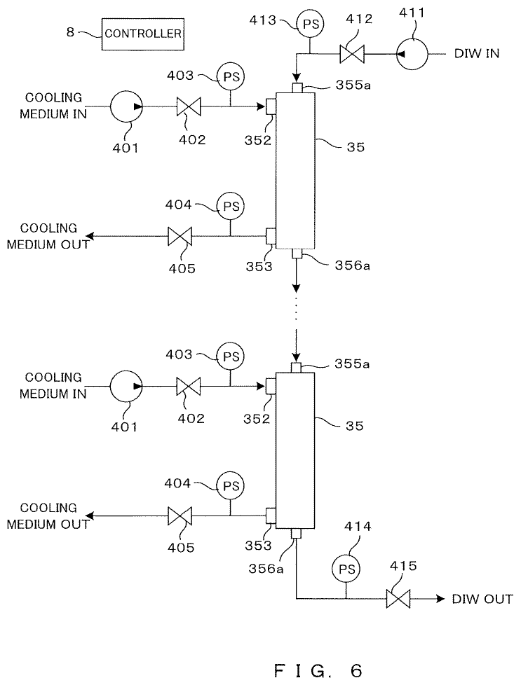

FIG. 6 shows an exemplary control method implemented when the cooling devices are connected in multiple stages. As shown in FIG. 6, if the cooling devices 3 are connected in multiple stages, the respective heat exchangers 35 in the cooling devices 3 are connected in series. The pressure control mechanism described above may be provided, in principle, to each of the heat exchangers 35. However, this is not always a realistic way as it causes excessively large pressure loss, particularly in a flow path of the DIW. In response to this, as shown in FIG. 6, pressure control can be performed using the pressure sensor 414 and the control valve 415 on the downstream side with respect to the most-downstream heat exchanger 35 among those connected in series.

In this case, the pressure of the DIW to be input differs between the heat exchangers 35, and assumes a smaller value with more closeness to the downstream side. This generates the need to perform pressure control on the side of the cooling medium in conformity with the pressure of the DIW in each heat exchanger 35.

In the configuration of this embodiment shown in FIGS. 1 and 2, it is possible to realize the above-described pressure control by causing the controller 8 to control control subjects including the feed pumps 222 and 332 and the control valves 226, 333, 335 and 336 on the basis of detection signals from the pressure sensors 223, 224, 338 and others provided along the flow paths.

As described above, in this embodiment, in order to supply the high-purity DIW as a processing liquid cooled to the predetermined target temperature to the substrate processor 9, the two-stage cooling process is employed by which the first cooling medium is cooled by the refrigerating circuit 31 as a chiller, and while the second cooling medium cooled through heat exchange with the first cooling medium is caused to circulate in the circulating liquid circuit 33, the DIW is cooled by the heat exchanger 35.

The heat exchanger 35 is provided with the inner pipes 354 penetrating the current space Sc for causing the second cooling medium to flow therein, and the DIW as the cooling target processing liquid flows in the internal space Sd of the inner pipe 354. The DIW is cooled through heat exchange conducted through the pipe wall of the inner pipe 354. The inner pipe 354 is a pipe made of fluorine resin. This prevents release of metal ions into the DIW before it occurs, which is a situation at issue in the case of using a metal pipe.

The resin pipe is lower in mechanical strength than a metal pipe and is exposed to the risk of break such as a crack under a high temperature. In this embodiment, the pressure of the cooling medium and that of the DIW existing across the pipe wall of the inner pipe 354 in the heat exchanger 35 are controlled in such a way as to bring the DIW to a higher pressure between the cooling medium and the DIW. Even if a crack is caused in the inner pipe 354, a resultant pressure difference still avoids mixture of the cooling medium into the DIW in the pipe. This prevents the occurrence of a situation where the DIW containing impurity will be supplied to the substrate processor 9 to contaminate a processing target.

As the specific embodiment has been illustrated and described above, the substrate processing system S corresponds to a “substrate processing apparatus” of the present invention. The cooling device 3 functions as a “cooling device” and a “cooler” of the present invention. Further, the substrate processor 9 functions as a “substrate processor” of the present invention. The pipe system 2, particularly the pipe 25 thereof functions as a “supply pipe” of the present invention.

Further, regarding the cooling device 3 of the above embodiment, the refrigerating circuit 31 and the circulating liquid circuit 33 integrally function as a “cooling medium supplier” of the present invention, and the heat exchanger 35 functions as a “heat exchanger” of the present invention. Further, the pipe system 2 functions as a “processing liquid supplier” of the present invention, and the controller 8 and each functional unit to be controlled by the controller 8 that is, for example, the control valve 226 integrally function as a “pressure regulator” of the present invention. The control valve 226 further functions as a “loss provider” of the present invention. Furthermore, the pressure sensor 224 functions as a “pressure detector” of the present invention.

Note that the invention is not limited to the above embodiment, and various changes other than the aforementioned ones can be made without departing from the gist of the invention. For example, while the heat exchanger 35 having a substantially circular columnar shape is used in the above embodiment, the shape of the heat exchanger 35 is not limited to this but can be determined freely. A rectangular columnar shape is applicable, for example.

Further, in the heat exchanger 35 of the above embodiment, the inner pipe 354 extends straight in the current space Sc from the one edge 351a toward the other edge 351b of the housing 351. Meanwhile, as the inner pipe 354 is a resin pipe having flexibility, it may be provided in a meandering pattern in the current space Sc. By increasing the length of a flow path of the DIW in this way in the current space Sc, it becomes possible to encourage improvement in cooling effect.

Further, in the above embodiment, the fluorine resin pipe is used for the reason that it prevents release of metal ions into the DIW. The pipe system 2 made of such a material having corrosion resistance allows a corrosive processing liquid to flow therein that may be an acidic chemical, for example. That is, in the cooling device 3 of the above embodiment, various types of chemicals in addition to pure water or DIW are applicable as a cooling target processing liquid.

As the specific embodiment has been illustrated and described above, in the cooling device according to the present invention, the pressure regulator may be configured to regulate at least one of the pressure of the cooling medium to flow into the current space and the pressure of the cooling medium to flow out of the current space, and at least one of the pressure of the processing liquid to flow into the one end and the pressure of the processing liquid to flow out of the other end, for example. By doing so, it becomes possible to maintain the pressure of the cooling medium and that of the processing liquid in the heat exchanger in a desirable relationship with each other.

As an example, if the pressure detector to detect the pressure of the processing liquid to flow out of the other end is provided further, the processing liquid supplier may be configured to cause the processing liquid to flow into the one end while the processing liquid is at a higher pressure than the cooling medium to flow into the current space, and the pressure regulator may be configured to make regulation in such a way that the pressure of the processing liquid detected by the pressure detector becomes higher than the pressure of the cooling medium to flow into the current space.

As a result of pressure loss in a flow path, the pressure of a liquid becomes lower with more closeness to the downstream side. Thus, in the heat exchanger, the pressure of each of the cooling medium and the processing liquid is considered to decrease monotonously in a corresponding flow direction. In this regard, by bringing the processing liquid to a higher pressure than the cooling medium in the stage of flowing into the heat exchanger and making the pressure of the processing liquid to flow out of the heat exchanger higher than the pressure of the cooling medium to flow into the heat exchanger, it becomes possible to fulfil the condition that the processing liquid be at a higher pressure than the cooling medium at any position in the heat exchanger. As a result, regardless of a position at which break in the inner pipe occurs, it is possible to avoid resultant mixture of the cooling medium into the processing liquid.

In particular, if the inner pipe is provided in such a way as to cause the processing liquid to flow from the one end toward the other end along a flow direction of the cooling medium in the current space, the pressure regulator may be configured to make regulation in such a way that the pressure of the processing liquid detected by the pressure detector becomes higher than the pressure of the cooling medium to flow out of the current space. If each of the processing liquid and the cooling medium has a pressure gradient decreasing monotonously toward the downstream side and the processing liquid and the cooling medium are to flow in the same flow direction, making the pressure of the processing liquid to flow out higher than the pressure of the cooling medium necessarily fulfills a condition that the processing liquid be at a higher pressure than the cooling medium at any position in the heat exchanger.

To achieve such a situation, a loss provider for increasing pressure loss of a flow path of the processing liquid may be provided in the flow path on the downstream side with respect to the other end, for example. This allows the pressure gradient of the processing liquid to be changed in the heat exchanger. By taking advantage of this, it is possible to maintain the desirable relationship between the pressures described above.

The loss provider to be used may include a control valve interposed in the flow path and regulated in a degree of opening by the pressure regulator, for example. In this configuration, the magnitude of pressure loss is regulated using a degree of opening of the control valve to achieve a desired pressure gradient.

As a example, if a plurality of the heat exchangers are connected in series with each other in the flow path of the processing liquid, the loss provider may be provided at least on the downstream side with respect to the most-downstream heat exchanger. Providing the loss provider to each of the heat exchangers connected in series with each other is not preferred as it might cause excessively large pressure loss in the entire flow path. In this case, the loss provider may be provided on the downstream side with respect to the most-downstream heat exchanger.

The heat exchanger may include a plurality of the inner pipes connected in parallel with each other in the current space. This increases the surface area of the inner pipes to achieve improvement in the effect of cooling the processing liquid.

De-ionized water or pure water is available as the processing liquid of the present invention, for example. In this case, while touch of the processing liquid with a metal pipe unavoidably causes release of metal ions, this problem can be settled by using a resin pipe. Specifically, the cooling device of the present invention is effective, particularly if de-ionized water or pure water is a cooling target. In this case, the inner pipe is preferably made of fluorine resin.

In the present invention, a relationship between a pressure and a flow rate at each part may be determined in advance through experiment or the like. By using the determined relationship as a basis, the controller may calculate a pressure at each part on the basis of a flow rate detected by a flow rate sensor instead of measuring a pressure at each part using a pressure sensor, and the calculated pressure may be used for control by the controller.

In controlling the pressure of the cooling medium or the DIW in the present invention, the controller may control the refrigerating circuit, the circulating liquid circuit, the heat exchanger and others for regulating the flow rate or pressure of the cooling medium or the DIW on the basis of a condition or a recipe defined in advance through experiment, for example.

This invention is applicable to each type of field that requires a processing liquid not containing impurity such as metal ions to become a contamination source and cooled to a lower temperature than room temperature. As an example, this invention is preferably applicable to processing of a semiconductor substrate, for example.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A cooling device for cooling a processing liquid and outputting the processing liquid, comprising:
a cooling medium supplier which supplies a cooling medium at a lower temperature than a cooling target temperature of the processing liquid;
a heat exchanger which is configured to cool the processing liquid through heat exchange with the cooling medium, the heat exchanger including a housing with a current space for causing the cooling medium supplied from the cooling medium supplier to flow therein and an inner pipe that is a resin pipe provided in and penetrating the current space in such a way that an outer surface of a pipe wall of the inner pipe borders the current space and an internal space of the inner pipe is separated from the current space;
a processing liquid supplier which supplies the processing liquid as a cooling target from one end of the inner pipe into the internal space of the inner pipe; and
a pressure regulator which is configured to regulate the pressure of the cooling medium inside the current space and the pressure of the processing liquid in the internal space, wherein:
the pressure regulator regulates at least one of the pressure of the cooling medium and the pressure of the processing liquid in such a way that the pressure of the processing liquid becomes higher than the pressure of the cooling medium between the cooling medium and the processing liquid facing each other across the pipe wall in the current space, and
the processing liquid which is cooled is output from an other end of the inner pipe opposite to the one end.

2. The cooling device according to claim 1, wherein the pressure regulator regulates at least one of the pressure of the cooling medium to flow into the current space and the pressure of the cooling medium to flow out of the current space, and at least one of the pressure of the processing liquid to flow into the one end and the pressure of the processing liquid to flow out of the other end.

3. The cooling device according to claim 1, further comprising a pressure detector which is configured to detect the pressure of the processing liquid to flow out of the other end, wherein
the processing liquid supplier causes the processing liquid to flow into the one end while the processing liquid is at a higher pressure than the cooling medium to flow into the current space, and
the pressure regulator makes regulation in such a way that the pressure of the processing liquid detected by the pressure detector becomes higher than the pressure of the cooling medium to flow into the current space.

4. The cooling device according to claim 3, wherein
the inner pipe is provided in such a way as to cause the processing liquid to flow from the one end toward the other end along a flow direction of the cooling medium in the current space, and
the pressure regulator makes regulation in such a way that the pressure of the processing liquid detected by the pressure detector becomes higher than the pressure of the cooling medium to flow out of the current space.

5. The cooling device according to claim 4, further comprising a loss provider for increasing pressure loss of a flow path of the processing liquid in the flow path on the downstream side with respect to the other end.

6. The cooling device according to claim 5, wherein the loss provider includes a control valve interposed in the flow path, and
the pressure regulator regulates a magnitude of the pressure loss by controlling a degree of opening of the control valve.

7. The cooling device according to claim 5, wherein a plurality of the heat exchangers are connected in series with each other in the flow path of the processing liquid, and
the loss provider is provided at least on the downstream side with respect to a most-downstream heat exchanger between the plurality of the heat exchangers.

8. The cooling device according to claim 1, wherein the heat exchanger includes a plurality of the inner pipes in the current space and the plurality of the inner pipes are connected in parallel with each other.

9. The cooling device according to claim 1, wherein the processing liquid is de-ionized water or pure water.

10. The cooling device according to claim 9, wherein the inner pipe is made of fluorine resin.

11. A substrate processing apparatus, comprising:
a cooler which includes the cooling device according to claim 1;
a substrate processor which is configured to process a substrate using the processing liquid output from the cooler; and
a supply pipe which supplies the processing liquid from the cooler to the substrate processor.

12. A cooling method to cooling a processing liquid and output the processing liquid, comprising:
causing a cooling medium at a lower temperature than a cooling target temperature of the processing liquid to flow in a heat exchanger including a housing with a current space and an inner pipe that is a resin pipe provided in and penetrating the current space in such a way that an outer surface of a pipe wall of the inner pipe borders the current space and an internal space of the inner pipe is separated from the current space and causing the processing liquid as a cooling target to flow from a one end of the inner pipe into the internal space;
regulating at least one of a pressure of the cooling medium and a pressure of the processing liquid in such a way that the pressure of the processing liquid becomes higher than the pressure of the cooling medium between the cooling medium and the processing liquid facing each other across the pipe wall in the current space; and
outputting the processing liquid which is cooled from an other end of the inner pipe opposite to the one end.
